(19) United States
(12) Patent Application Publication
(10) Pub. No.: US 2004/0218367 A1
(43) Pub. Date: Nov. 4, 2004

(54) Function module with built-in heat dissipation fin

(76) Inventors: Wen-Yen Lin, Taoyuan City (TW); Tsan-Nan Chien, Taipei (TW); Chun-Wen Pai, Jhonghe City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/824,090

(22) Filed: Apr. 14, 2004

(30) Foreign Application Priority Data
Apr. 29, 2003 (TW) 92109974

(51) Int. Cl. H05K 7/20

(52) U.S. Cl. 361/721; 361/720

(57) ABSTRACT

A function module with a built-in heat dissipation fin. The function module includes a first circuit board, a second circuit board, and a heat dissipation fin. The first circuit board includes a first surface with a first ground layer formed thereon. The second circuit board is coupled to the first circuit board, and includes a second surface facing the first surface. A second ground layer is formed on the second surface. The heat dissipation fin is disposed between the first circuit board and the second circuit board, and abuts the first ground layer and the second ground layer respectively.

### BACKGROUND OF THE INVENTION

1. Field of the Invention

The invention relates to a function module; in particular, to a function module with a built-in heat dissipation fin.

2. Description of the Related Art

Generally, a printed circuit board of an electronic apparatus includes many electronic devices and operating circuits distributed thereon. When the electronic apparatus is operated, electronic devices will produce heat and increase temperature inside the electronic apparatus such that the efficiency of the electronic is device may be inhibited, and an excessive temperature increase may lead to device malfunction. Therefore, a heat dissipation device is necessary on printed circuit boards for dissipation of produced heat.

In addition, as semiconductor technology process has evolved, the operating speeds thereof have increased accordingly, such that a single electronic device may now incorporate multiple functions. However, due to such designs, it is difficult to simultaneously control heat dissipation, signal quality, and electromagnetic radiation in the electronic device.

As stated above, electronic devices communicate via the circuit board. Referring to FIG. 1, in a computer system 10, electronic devices, such as a central processing unit (CPU) 1, chipset 2, graphics processing unit (GPU) or accelerated graphics port (AGP) 3, or dynamic random access memory (DRAM) 4, are disposed in different areas of a motherboard 7. To solve heat dissipation problems for each electronic device, a conventional solution is provided for each electronic device.

For example, a combination of a heat dissipation fin, a heat pipe, and a fan is typically employed for CPUs. The heat dissipation fin and/or the fan are usually used for the chipset or the GPU. As shown in FIG. 2, a heat dissipation module 20 is disposed on the CPU 1 of the computer system. The heat dissipation module 20 includes a heat spreader 21, a heat pipe 22, a heat dissipation fin 23, and a fan 24. The heat spreader 21 uniformly spreads the heat energy of the CPU 1 to the heat spreader 21 over a larger area so as to reduce the thermal intensity of the surface of the CPU 1. The heat pipe 22 transfers the heat energy to the heat dissipation fin 23. The fin 23 spreads the heat energy over its larger area. The fan 24 exhausts heat from the system.

However, the conventional solution does not adequately solve the heat dissipation problem with regard to a motherboard with a plurality of electronic devices thereon. Thus, a more efficient heat dissipation device is required. However, such solutions are conventionally only suitable for use on a flat surface. That is, the varying heights of each electronic device rule out the disposition of the conventional heat dissipation device on the PCB. Thus, disposition of the heat dissipation device on a PCB with varied height surface remains a problem.

### SUMMARY OF THE INVENTION

In view of this, the invention provides a function module with a built-in heat dissipation fin.

In this invention, a function module with a built-in heat dissipation fin is provided. The function module includes a first circuit board, a second circuit board, and a heat dissipation fin. The first circuit board includes a first surface with a first ground layer formed thereon. The second circuit board is coupled to the first circuit board, and includes a second surface facing the first surface. A second ground layer is formed on the second surface. The heat dissipation fin is disposed between the first circuit board and the second circuit board, and abuts the first ground layer and the second ground layer respectively.

In a preferred embodiment, the first circuit board further includes a third surface, opposite to the first surface, with a first device located thereon.

In another preferred embodiment, the second circuit board further includes a fourth surface, opposite to the second surface, with a second device located thereon.

It is understood that both the first ground layer and the second ground layer may be made of copper, and have a thickness not substantially less than 1.5 mil.

In another preferred embodiment, the function module further includes a fan, connecting to the heat dissipation fin, for dissipating heat therefrom.

In another preferred embodiment, the function module further includes a first heat spreader and a second heat spreader. The first heat spreader is disposed between the heat dissipation fin and the first ground layer, and uniformly spreads the heat over the first circuit board. The second heat spreader is disposed between the heat dissipation fin and the second ground layer, and uniformly spreads the heat over the second circuit board.

Furthermore, both the first heat spreader and the second heat spreader are made of copper, aluminum, metallic composite material, or non-metallic composite material, and the thermal conductivity of each is not less than 100 W/m·K.

In another preferred embodiment, the function module further includes a first adhesion layer and a second adhesion layer. The first adhesion layer is disposed between the heat dissipation fin and the first ground layer, and combines the heat dissipation fin with the first circuit board. The second adhesion layer is disposed between the heat dissipation fin and the second ground layer, and combines the heat dissipation fin with the second circuit board.

It is understood that both the first adhesion layer and the second adhesion layer may be made of brazing solder, tin solder, thermal interface material, or grease.

In this invention, another function module with a built-in heat dissipation fin is provided. The function module includes a first circuit board, a second circuit board, and a heat dissipation fin. The first circuit board includes a first surface with a first heat conduction layer formed thereon. The second circuit board is coupled to the first circuit board, and includes a second surface facing the first surface. A second heat conduction layer is formed on the second surface. The heat dissipation fin is disposed between the first circuit board and the second circuit board, and abuts the first heat conduction layer and the second heat conduction layer respectively.

In a preferred embodiment, the first heat conduction layer is a ground layer of the first circuit board, and the second heat conduction layer is a ground layer of the second circuit board.

In a preferred embodiment, the first heat conduction layer is a power source surface of the first circuit board, and the second heat conduction layer is a power source surface of the second circuit board.

### BRIEF DESCRIPTION OF THE DRAWINGS

The present invention can be more fully understood by reading the subsequent detailed description and examples with references made to the accompanying drawings, wherein:

FIG. 1 is a schematic view of a conventional computer system;

FIG. 2 is a schematic view showing a conventional heat dissipation module disposed on a CPU in FIG. 1;

FIG. 3 is a schematic view of a function module as disclosed in this invention;

FIG. 4a is an exploded view of a function module, with a built-in heat dissipation fin, as disclosed in this invention;

FIG. 4b is a schematic view of the assembled function module in FIG. 4a;

FIG. 5a is a side view of a varied embodiment of the assembled function module in FIG. 4a;

FIG. 5b is a side view of another varied embodiment of the assembled function module in FIG. 4a;

FIG. 6 is a schematic view of another varied embodiment of the assembled function module in FIG. 4a;

FIG. 7a is a cross section of a built-up circuit board; and

FIG. 7b is a cross section of a circuit board with a through hole.

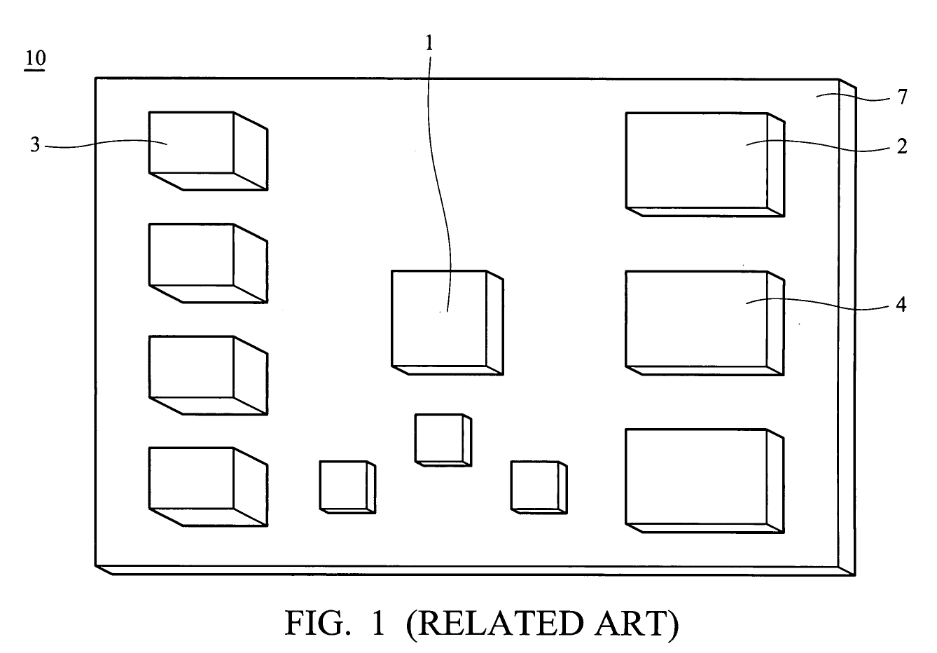

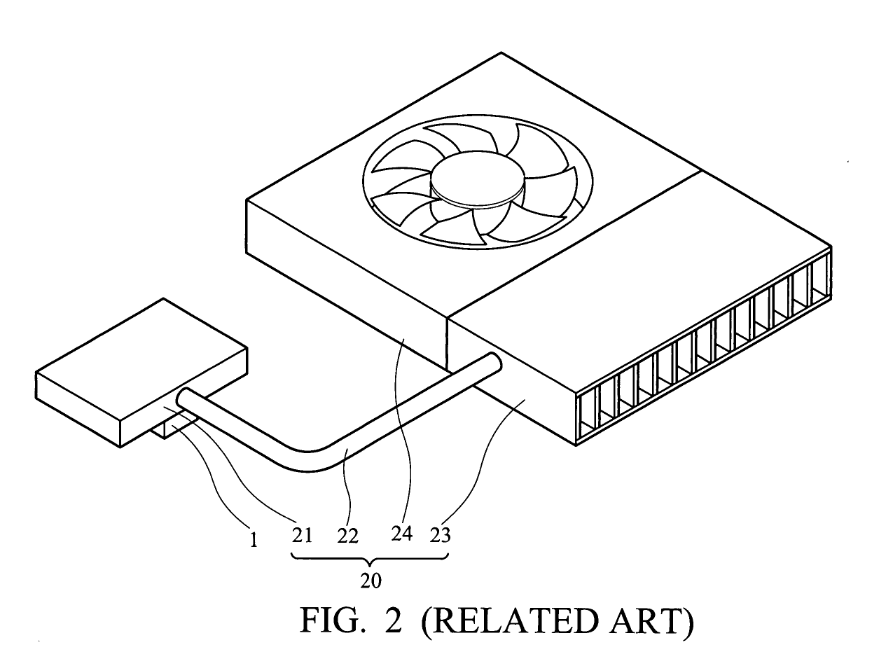

### DETAILED DESCRIPTION OF THE INVENTION

As the operating speed of electronic devices increases, the transmission speed of the front side bus (FSB) of the computer has increased from 333 MHz to 800 MHz. Thus, a single chip may incorporate multiple functions. Specifically, an electronic device, such as a CPU, a north bridge, or a GPU, located on the front side bus is provided with multiple functions.

Accordingly, it is difficult to simultaneously control heat dissipation, signal quality, and electromagnetic radiation in the electronic device. Thus, it is difficult to design the front side bus on the motherboard. In addition, the number of pins of the electron device increases accordingly. Thus, a high density interconnect (HDI) is provided as the circuit board of the computer system.

A function module, as disclosed in this invention, is provided with the above mentioned high-speed and high-density devices, solving heat dissipation problems thereof. Electronic devices with high speed transmission such as, CPU, north bridge, GPU or AGP, DRAM or GRAM, are disposed on a HDI. Via the HDI, high speed devices communicate with each other to constitute an independent function module. The function module can be coupled to a printed circuit board with other devices via a connector, a flat cable, or solder, to constitute a complete motherboard of the computer. Thus, problems created by high speed devices are solved, and the cost is is effectively reduced.

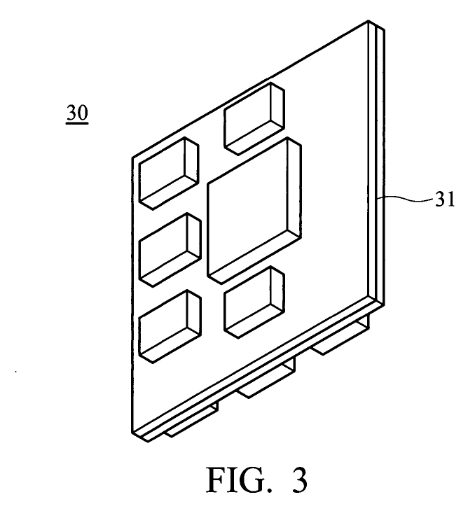

Referring to FIG. 3, a function module 30 of the invention is shown. For a function module with more devices or with devices having different functions, the devices can be disposed on both surfaces of the function module 30 according to function. For example, the devices can be disposed on the surfaces of the function module 30 by surface mount technology (SMT). To promote the quality of the high frequency signal and provide power, a ground layer 31 is disposed in the function module 30.

However, when all the high speed devices are disposed on the function module, heat originally generated on the motherboard, is also concentrated on the function module. Furthermore, since the high speed devices are disposed in a relatively small area, it is difficult to provide heat-dissipation for each device.

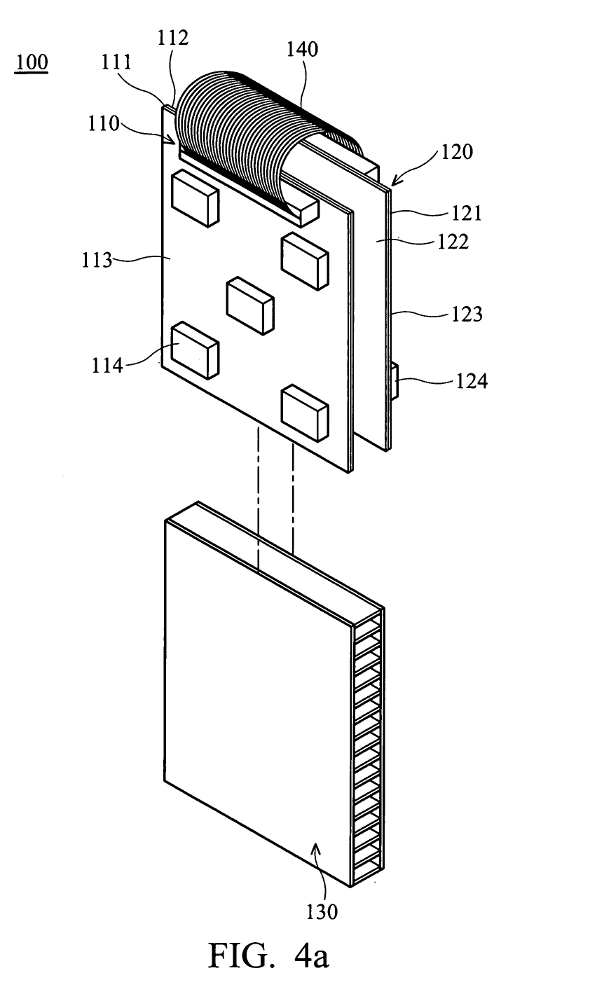

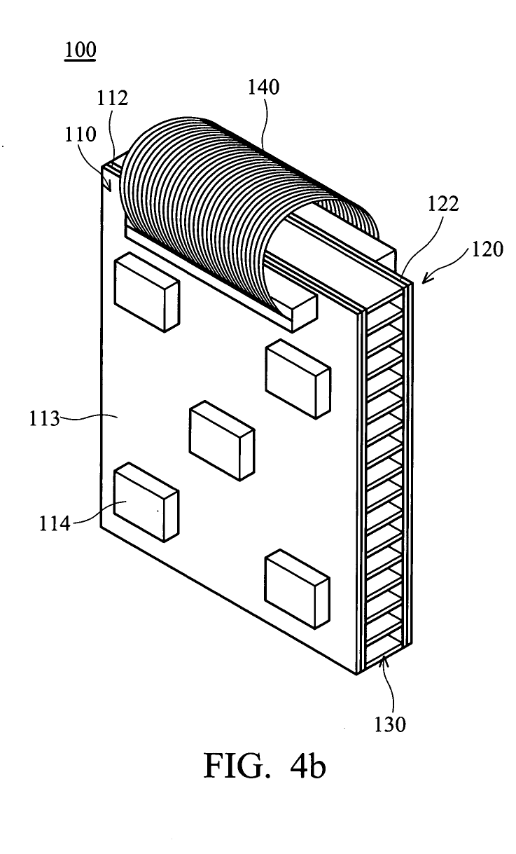

To effectively dissipate heat therefrom, the function module 30 as shown in FIG. 3 can be modified so that the heat dissipation device can be utilized more effectively. FIGS. 4a-4b show another function module 100, with a built-in heat dissipation fin, as disclosed in this invention. It is understood that the function module 100 is designed based on the function module 30 as shown in FIG. 3. Specifically, the function module 30 is divided into two circuit boards.

Referring to FIGS. 4a-4b, the function module 100 includes a first circuit board 110, a second circuit board 120, a heat dissipation fin 130, and a flat cable 140. Both the first circuit board 110 and the second circuit board 120 may be made of HDI. As shown in FIG. 4a, the first circuit board 110 includes a first surface 111 and a third surface 113 opposite to the first surface 111. A first ground layer 112 is formed on the first surface 111, and a plurality of first devices 114 is disposed on the third surface 113. The first ground layer 112 is used as a heat conduction layer of the first circuit board 110. Thus, the heat from the first circuit board 110 can be quickly and uniformly conducted to the heat dissipation fin 130. It is understood that the first ground layer 112 may be made of copper, and the thickness of the first ground layer 112 is substantially not less than 1.5 mil.

As shown in FIG. 4a, the second circuit board 120 is coupled to the first circuit board 110 via the flat cable 140, and includes a second surface 121, facing the first surface 111, and a fourth surface 123 opposite to the second surface 121. A second ground layer 122 is formed on the second surface 121, and a plurality of second devices 124 is disposed on the fourth surface 123. The second ground layer 122 is used as a heat conduction layer of the second circuit board 120. Thus, the heat from the second circuit board 120 can be quickly and uniformly conducted to the plate-type heat dissipation device 130. It is understood that the second ground layer 122 may be made of copper, and the thickness of the second ground layer 122 is not substantially less than 1.5 mil.

It is noted that both the first ground layer 112 and the second ground layer 122 may be used as a power source surface respectively.

As shown in FIG. 4b, the heat dissipation fin 130 is disposed between the first circuit board 110 and the second circuit board 120, and abuts the first ground layer 112 and the second ground layer 122 respectively.

As shown in FIGS. 4a-4b, the flat cable 140 connects the first circuit board 110 and the second circuit board 120, providing communicability therebetween. In addition, the first circuit board 110 may be coupled to the second circuit board without the flat cable. For example, a connector or a slot connector may be used to communicate the first circuit board 110 and the second circuit board 120.

To manufacture the function module 100, the first circuit board 110 is firstly coupled to the second circuit board 120 via the flat cable 140. Then, the first ground layer 112 of the first circuit board 110 faces the second ground layer 122 of the second circuit board 120 as shown in FIG. 4a. Finally, the heat dissipation fin 130 is disposed between the first circuit board 110 and the second circuit board 120 so as to obtain the function module 100 as shown in FIG. 4b.

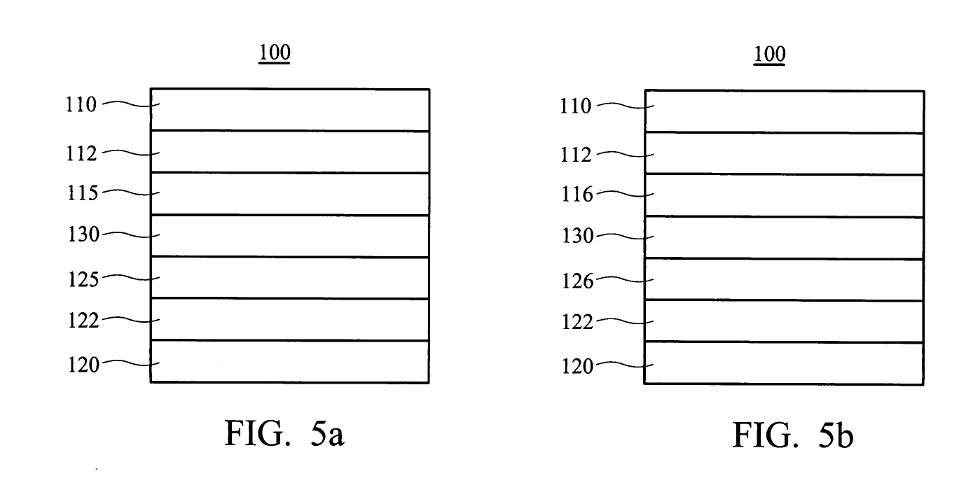

In addition, when the thickness of the ground layer is insufficient to uniformly spread the heat generated by the circuit board, a heat spreader may be additionally disposed on the ground layer. Specifically, referring to FIG. 5a, the function module 100 may further include a first heat spreader 115 and a second heat spreader 125.

The first heat spreader 115 is disposed between the heat is dissipation fin 130 and the first ground layer 112, and uniformly spread the heat over the first circuit board 110. The second heat spreader 125 is disposed between the heat dissipation fin 130 and the second ground layer 122, and uniformly spread the heat over the second circuit board 120.

In addition, when the thickness of a base (not labeled), abutting the first ground layer 112 and the second ground layer 122, of the heat dissipation fin 130 is sufficient to spread the heat, the base can be used as a heat spreader. Thus, the first heat spreader 115 and the second heat spreader 125 are not required.

Furthermore, both the first heat spreader 115 and the second heat spreader 125 are made of copper, aluminum, metallic composite material, or non-metallic composite material, and the thermal conductivity of each is not less than 100 W/m·K.

Furthermore, referring to FIG. 5b, the function module 100 may further include a first adhesion layer 116 and a second adhesion layer 126. The first adhesion layer 116 is disposed between the heat dissipation fin 130 and the first ground layer 112, and combines the heat dissipation fin 130 with the first circuit board 110.

The second adhesion layer 126 is disposed between the heat dissipation fin 130 and the second ground layer 122, and combines the heat dissipation fin 130 with the second circuit board 120.

It is understood that both the first adhesion layer 116 and the second adhesion layer 126 may be made of is brazing solder, tin solder, thermal interface material, or grease.

In addition, the first circuit board 110 may be coupled to the second circuit board 120 without the flat cable. For example, a connector or a slot connector may be used to communicate the first circuit board 110 and the second circuit board 120.

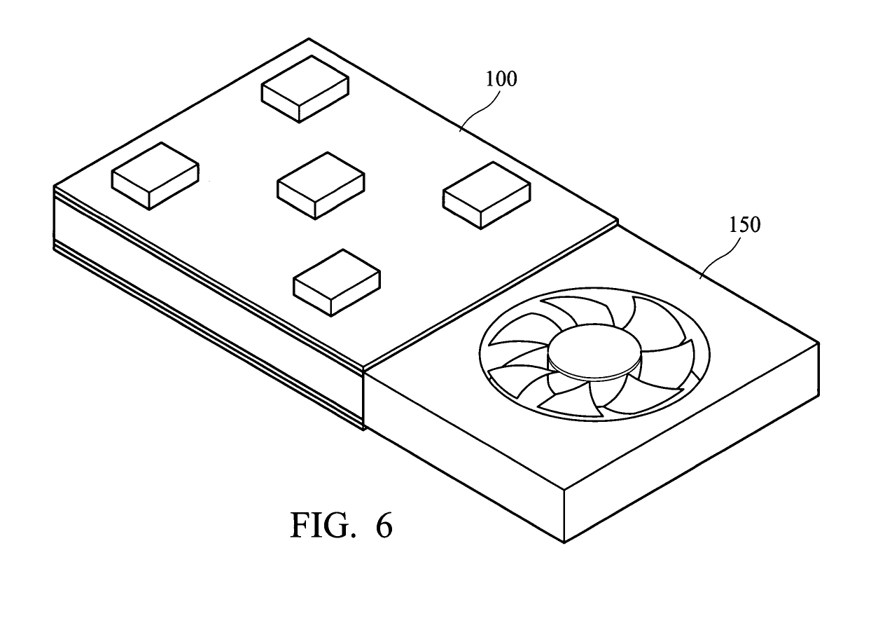

Furthermore, referring to FIG. 6, the function module 100 may further include a fan 150, connecting to the heat dissipation fin 130, for dissipating heat from the function module 100 to the surrounding area.

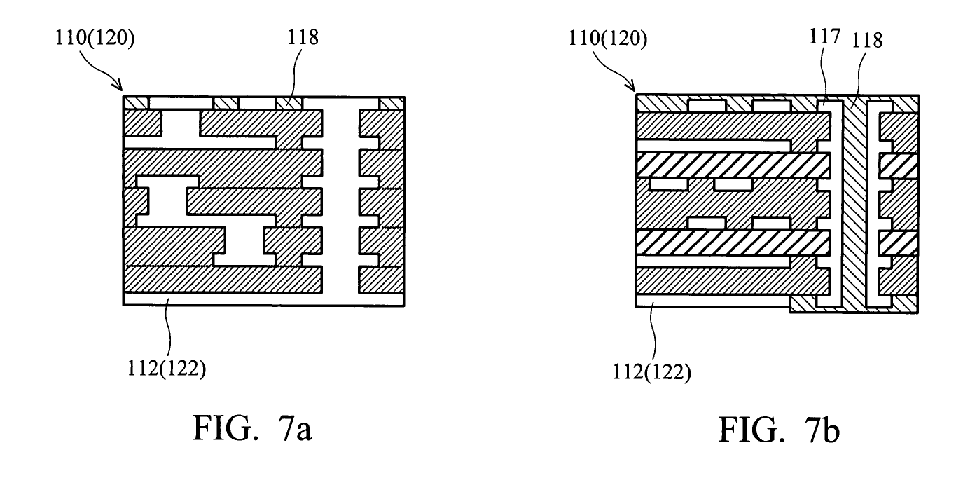

Furthermore, both the first circuit board 110 and the second circuit board 120 may be manufactured by forming blind holes on a copper plate (or other metal plate) in a build-up method as shown in FIG. 7a. In addition, as shown in FIG. 7b, both the first circuit board 110 and the second circuit board 120 may be manufactured by forming a through hole 117 on the printed circuit board. To prevent the tin solder from entering into the through hole 117 during manufacture, the through hole 117 is partially covered by a solder mask 118. Thus, the non-ground hole is protected from short-circuiting.

As stated above, the function module includes two circuit boards, each including a ground surface (or power surface) made of copper. By combining the heat dissipation fin with the flat ground surfaces, a function module with a sandwich-type structure is obtained. The heat over the function module can thus be quickly and uniformly conducted to the plate-type heat dissipation device. Furthermore, the heat from the function module can also be introduced out of the function module by the fan.

In addition, in the function module with the sandwich-typed structure, the ground surface on the circuit board can be used as a heat spreader so that the heat from the devices on the circuit board can be uniformly distributed over the ground surface. By directly combining the ground surface with the heat dissipation fin, additional heat pipe is not required. Thus, both the cost and the thermal resistance can be reduced.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A function module comprising:
a first circuit board including a first surface with a first ground layer formed thereon;
a second circuit board, coupled to the first circuit board, including a second surface facing the first surface, wherein a second ground layer is formed on the second surface; and
a heat dissipation fin, disposed between the first circuit board and the second circuit board, abutting the first ground layer and the second ground layer respectively.

2. The function module as claimed in claim 1, wherein the first circuit board further includes a third surface, opposite to the first surface, with a first device located thereon.

3. The function module as claimed in claim 1, wherein the second circuit board further includes a fourth surface, opposite to the second surface, with a second device located thereon.

4. The function module as claimed in claim 1, wherein both the first ground layer and the second ground layer are made of copper.

5. The function module as claimed in claim 1, wherein both the thickness of the first ground layer and the thickness of the second ground layer are substantially not less than 1.5 mil.

6. The function module as claimed in claim 1, further comprising a flat cable connecting the first circuit board and the second circuit board, providing communicability therebetween.

7. The function module as claimed in claim 1, further comprising a connector connecting the first circuit board and the second circuit board, providing communicability therebetween.

8. The function module as claimed in claim 7, wherein the connector is a slot connector.

9. The function module as claimed in claim 1, further comprising:
a first heat spreader, disposed between the heat dissipation fin and the first ground layer, for uniformly spreading the heat over the first circuit board; and
a second heat spreader, disposed between the heat dissipation fin and the second ground layer, for uniformly spreading the heat over the second circuit board.

10. The function module as claimed in claim 9, wherein both the first heat spreader and the second heat spreader are made of copper, aluminum, metallic composite material, or non-metallic composite material.

11. The function module as claimed in claim 9, wherein both the thermal conductivity of the first heat spreader and the thermal conductivity of the second heat spreader are not substantially, less than 100 W/me K.

12. The function module as claimed in claim 1, further comprising:
a first adhesion layer, disposed between the heat dissipation fin and the first ground layer, for combining the heat dissipation fin with the first circuit board; and
a second adhesion layer, disposed between the heat dissipation fin and the second ground layer, for combining the heat dissipation fin with the second circuit board.

13. The function module as claimed in claim 12, wherein both the first adhesion layer and the second adhesion layer comprise one selected from the group consisting of brazing solder, tin solder, thermal interface material, grease and the combination thereof respectively.

14. The function module as claimed in claim 1, further comprising a fan, connected to the heat dissipation fin, for dissipating heat therefrom.

15. A function module comprising:
a first circuit board including a first surface with a first heat conduction layer formed thereon;
a second circuit board, coupled to the first circuit board, including a second surface facing the first surface, wherein a second heat conduction layer is formed on the second surface; and
a heat dissipation fin disposed between the first circuit board and the second circuit board, abutting the first heat conduction layer and the second heat conduction layer respectively.

16. The function module as claimed in claim 15, wherein the first heat conduction layer is a ground layer of the first circuit board, and the second heat conduction layer is a ground layer of the second circuit board.

17. The function module as claimed in claim 15, wherein the first circuit board further includes a third surface, opposite to the first surface, with a first device located thereon.

18. The function module as claimed in claim 15, wherein the second circuit board further includes a fourth surface, opposite to the second surface, with a second device located thereon.

19. The function module as claimed in claim 15, wherein both the first heat conduction layer and the heat conduction layer are made of copper.

20. The function module as claimed in claim 15, wherein both the thickness of the first heat conduction layer and the thickness of the second heat conduction layer are not substantially less than 1.5 mil.

21. The function module as claimed in claim 15, further comprising a flat cable connecting the first circuit board and the second circuit board, providing communicability therebetween.

22. The function module as claimed in claim 15, further comprising a connector connecting the first circuit board and the second circuit board, providing communicability therebetween.

23. The function module as claimed in claim 22, wherein the connector is a slot connector.

24. The function module as claimed in claim 15, further comprising:
a first heat spreader, disposed between the heat dissipation fin and the first heat conduction layer, for uniformly spreading the heat over the first circuit board; and
a second heat spreader, disposed between the heat dissipation fin and the second heat conduction layer, for uniformly spreading the heat over the second circuit board.

25. The function module as claimed in claim 24, wherein both the first heat spreader and the second heat spreader are made of copper, aluminum, metallic composite material, or non-metallic composite material.

26. The function module as claimed in claim 15, wherein both the thermal conductivity of the first heat spreader and the thermal conductivity of the second heat spreader are substantially not less than 100 W/m·K.

27. The function module as claimed in claim 15, further comprising:
a first adhesion layer, disposed between the heat dissipation fin and the first heat conduction layer, for combining the heat dissipation fin with the first circuit board; and
a second adhesion layer, disposed between the heat dissipation fin and the second heat conduction layer, for combining the heat dissipation fin with the second circuit board.

28. The function module as claimed in claim 27, wherein both the first adhesion layer and the second adhesion layer comprise one selected from the group consisting of brazing solder, tin solder, thermal interface material, grease and the combination thereof respectively.

29. The function module as claimed in claim 15, further comprising a fan, connected to the heat dissipation fin, for dissipating heat therefrom.

30. The function module as claimed in claim 15, wherein the first heat conduction layer is a power source surface of the first circuit board, and the second heat conduction layer is a power source surface of the second circuit board.
